(19) United States
(12) Patent Application Publication
(10) Pub. No.: US 2007/0030636 A1
(43) Pub. Date: Feb. 8, 2007

(54) Portable computer

(75) Inventor: Myung-jun Kim, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/496,504

(22) Filed: Aug. 1, 2006

(30) Foreign Application Priority Data
Aug. 4, 2005 (KR) 2005-71251

(51) Int. Cl. G06F 1/16; H05K 5/00

(52) U.S. Cl. 361/683; 361/681

(57) ABSTRACT

A portable computer includes a computer main body, and a display part connected to the computer main body and having a display panel to display an image thereon, a plurality of coupling parts which are formed on opposite side walls of the display panel, a support bracket which supports the opposite side walls of the display panel and varies in length, and having a pair of supporters slidably coupled to each other, and a coupling member which is coupled to one of the plurality of coupling parts to couple the support bracket to the display panel. Thus, the portable computer having the support bracket which varies in length according to a size of a display panel is used for display panels of various sizes.

### CROSS-REFERENCE TO RELATED APPLICATIONS

This application claims the benefit of Korean Patent Application No. 2005-0071251, filed on Aug. 4, 2005, in the Korean Intellectual Property Office, the disclosure of which is incorporated herein by reference in its entirety.

### BACKGROUND OF THE INVENTION

1. Field of the Invention

The present general inventive concept relates to a portable computer, and more particularly, to a portable computer having a support bracket which is usable with display panels of various sizes.

2. Description of the Related Art

Generally, a portable computer comprises a computer main body having a plurality of hardware, and a display part which is rotatably coupled to the computer main body to display an image thereon.

The display part comprises a display panel to display the image thereon, and a front and rear cover which support the display panel.

Here, opposite lateral sides of the display panel are supported by a pair of brackets. By way of example, Korean Patent First Publication No. 2002-0011043 describes a size adaptive liquid crystal display (LCD) bracket to stably fix LCD panels of various sizes to a single rear panel while compensating for different sizes of the LCD panels with a length difference between inner bending parts.

In a conventional portable computer, since the LCD bracket is provided with the inner bending parts, there is no need to replace the entire rear panel when exchanging the LCD panel. However, the LCD brackets must be additionally manufactured for supporting display panels of 13 and 14 inches.

### SUMMARY OF THE INVENTION

Accordingly, the present general inventive concept provides a portable computer having a support bracket which varies in length according to a size of a display panel and can be used for display panels of various sizes.

Additional aspects of the present general inventive concept will be set forth in part in the description which follows and, in part, will be obvious from the description, or may be learned by practice of the present general inventive concept.

The foregoing and/or other aspects of the present general inventive concept are achieved by providing a portable computer, comprising a computer main body, a display part connected to the computer main body and having a display panel to display an image thereon, a plurality of coupling parts formed on opposite side walls of the display panel, a support bracket which supports the opposite side walls of the display panel and varies in length, and having a pair of supporters slidably coupled to each other, and a coupling member which is coupled to one of the plurality of coupling parts to couple the support bracket to the display panel.

A first one of the supporters may be provided with a guiding part in a lengthwise direction, and a second one of the supporters may be slidably accommodated in the guiding part.

The supporters may comprise opening parts which penetrate a plate surface thereof along a lengthwise direction, and the opening parts may communicate with each other.

The coupling member may comprise a screw which is coupled to the respective coupling part through both the opening parts.

The display part may comprise a front cover which supports the display panel at a front thereof, and a rear cover which supports the display panel therebehind.

The supporters may comprise a flange which is coupled to the rear cover.

The portable computer may further comprise a hinge assembly which rotatably couples the display part to the computer main body, and the flange provided in the supporters is adjacent to the computer main body and is coupled to the rear cover together with the hinge assembly.

The foregoing and/or other aspects of the present general inventive concept are also achieved by providing a portable computer, comprising a computer main body, a display part connected to the computer main body and having a display panel to display an image thereon, a plurality of coupling parts which are formed on opposite side walls of the display panel, a support bracket which supports the opposite side walls of the display panel and varies in length, and having a pair of supporters with respective portions that are overlapped with each other, and a coupling member which is coupled to one of the coupling parts to couple the support bracket to the display panel.

The supporters may comprise opening parts which penetrate a plate surface thereof along a lengthwise direction through which the coupling member is inserted, and the opening parts communicate with each other.

The foregoing and/or other aspects of the present general inventive concept are also achieved by providing a portable computer, comprising a main body part, a display part hingeably connected to the main body part and having a display side, a rear side, and lateral sides extending between the display side and the rear side, the lateral sides having coupling holes, and an adjustable support bracket coupled to at least one of the lateral sides of the display part via the coupling holes, the support bracket including a first supporter extending along a lower portion of the lateral side and a second supporter extending along an upper portion of the lateral side such that the first and second supporters overlap with each other at a middle portion of the lateral side.

The foregoing and/or other aspects of the present general inventive concept are also achieved by providing an adjustable support bracket to support a display part usable with a portable computer, the support bracket comprising a second supporter plate to be coupled to a lateral side of the display part along a second portion of a length thereof, and a first supporter plate to be coupled to the lateral side of the display part along a first portion of the length thereof to overlap with the second supporter plate and having a guiding part to engage the second supporter plate to form a track along which the first and second supporter plates are slidable with respect to each other.

The foregoing and/or other aspects of the present general inventive concept are also achieved by providing a support bracket usable to support display panels of various sizes, the support bracket comprising a bracket assembly having first and second plates to be coupled to one or more lateral sides of a display panel at first and second ends of the lateral sides, respectively, the first and second plates having an overlap area with respect to each other that is adjustable such that a size of the bracket assembly is adjustable to allow the first and second plates to collectively extend along lengths of the lateral sides.

The foregoing and/or other aspects of the present general inventive concept are also achieved by providing a support bracket usable to support display panels of various sizes, the support bracket comprising a first supporter plate having a first coupling portion extending therethrough, a second supporter plate having a second coupling portion extending therethrough, and a guiding part to slidably couple the first and second supporter plates together. The a plurality of couplers extend through the first and second coupling portions to couple the first and second supporter plates to a lateral side of a display part.

### BRIEF DESCRIPTION OF THE DRAWINGS

The above and/or other aspects of the present general inventive concept will become apparent and more readily appreciated from the following description of the embodiments, taken in conjunction with the accompanying drawings of which:

FIG. 1 is a perspective view illustrating a portable computer according to an embodiment of the present general inventive concept;

FIG. 2 is an exploded perspective view illustrating a display panel of the portable computer of FIG. 1;

FIG. 3 is an exploded view illustrating a support bracket of the display panel of FIG. 2, according to an embodiment of the present general inventive concept;

FIG. 4A is an enlarged view illustrating a small-sized display panel and the support bracket of FIG. 3;

FIG. 4B is an enlarged view illustrating a large-sized display panel and the support bracket of FIG. 3;

FIG. 5A is an enlarged view illustrating a small-sized display panel and a support bracket according to another embodiment of the present general inventive concept; and

FIG. 5B is an enlarged view illustrating a large-sized display panel and the support bracket of FIG. 5A according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

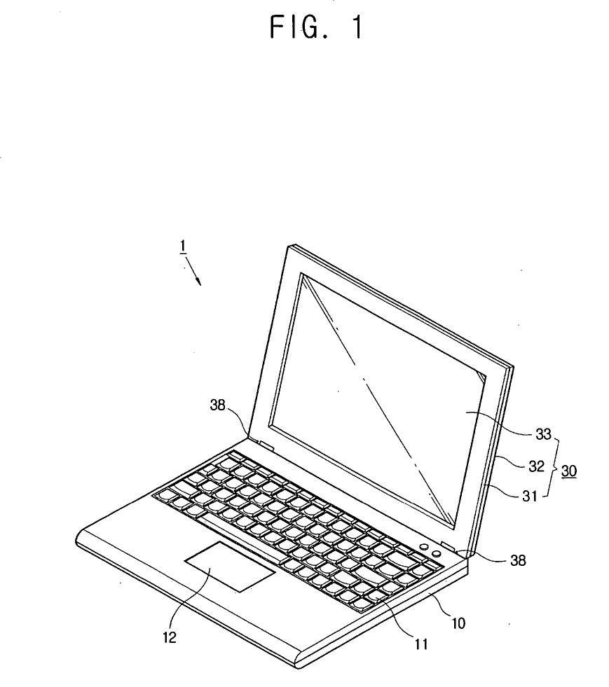

As illustrated in FIG. 1, a portable computer 1 according to an embodiment of the present general inventive concept comprises a computer main body 10 and a display part 30 which is connected to the computer main body 10 to display an image thereon.

A plurality of hardware components including a main board, a central processing unit (CPU), and a random access memory (RAM) are accommodated inside of the computer main body 10. A keyboard 11 and a touch pad 12 may be provided on an outside of the computer main body 10.

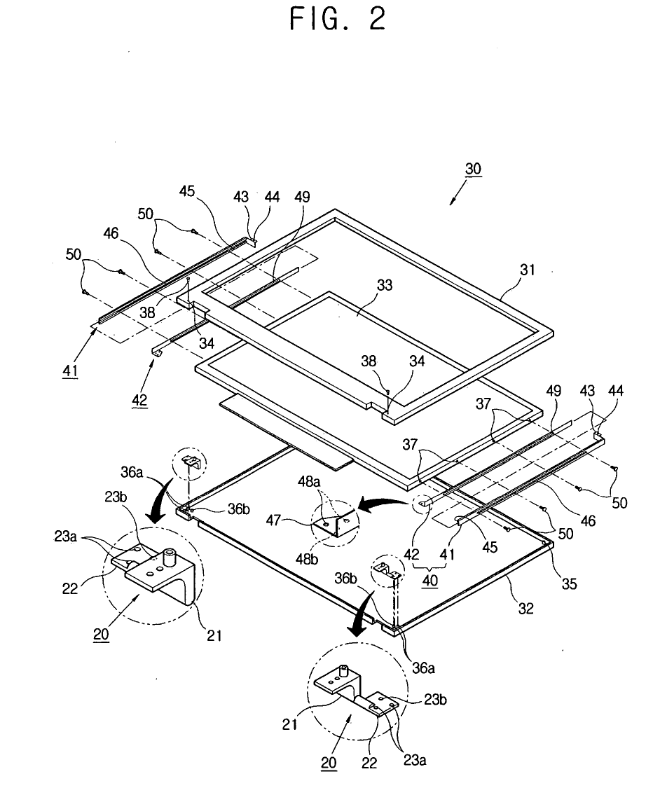

As illustrated in FIGS. 1 and 2, the display part 30 comprises a display panel 33 which displays the image thereon, a front cover 31 which supports the display panel 33 at a front thereof, a rear cover 32 which is coupled to the front cover 31 to support the display panel 33 therebehind, and a pair of support brackets 40 which support the display panel 33 at opposite lateral sides thereof. The display part 30 is rotatably supported by a hinge assembly 20 to the computer main body 10.

A plurality of panel coupling holes 37 are formed on opposite end parts of the display panel 33 to be respectively coupled to the support brackets 40.

A through hole 34 penetrates a plate surface of the front cover 31. A cover screw 38 which is inserted into the through hole 34 is coupled to a cover boss 36b of the rear cover 32 (to be described below).

A bracket boss 35 is provided on an upper part of the rear cover 32. A pair of coupling bosses 36a is also provided on a lower part of the rear cover 32 to be adjacent to the cover boss 36b.

The support brackets 40 comprise a first supporter 41 and a second supporter 42 which are slidably coupled to each other and vary in length according to a length of the opposite lateral sides of the display panel 33 supported by the support brackets 40.

The first supporter 41 is provided with a guiding part 45 which guides the second supporter 42 to slide along a lengthwise direction thereof, and a first opening part 46 which is coupled with screws 50.

A first coupling part 43 is provided on an upper part of the first supporter 41 to be coupled with the rear cover 32. A first through hole 44 penetrates a plate surface of the first coupling part 43. As a screw (not shown) is coupled to the bracket boss 35 of the rear cover 32 through the first through hole 44, the first supporter 41 is fixed to the rear cover 32.

The second supporter 42 is slidably accommodated in the guiding part 45 of the first supporter 41, and comprises a second opening part 49 lining up with the first opening part 46 to be coupled with the screws 50 as a coupling member.

A second coupling part 47 is provided on a lower part of the second supporter 42. A plurality of second through holes 48a and 48b penetrate a plate surface of the second coupling part 47. Among the plurality of second through holes 48a and 48b, a single second through hole 48b is coupled with a coupling projection (not shown) which is provided on the rear cover 32, and a pair of second through holes 48a are coupled to the hinge assembly 20 by the screw (not shown).

The hinge assembly 20 comprises a main body coupling part 21 which is coupled to the computer main body 10, and a bracket coupling part 22 which is rotatably coupled to the main body coupling part 21 and fixed to the front cover 31 and the rear cover 32. That is, the bracket coupling part 22 is fixed to the front and rear covers 31 and 32 to be rotatably coupled with the main body coupling part 21 fixed to the computer main body 10, thereby rotating the display part 30 with respect to the computer main body 10.

The bracket coupling part 22 comprises a plurality of coupling holes 23a and 23b which penetrate a plate surface thereof. The screw (not shown) is coupled to the coupling boss 36a of the rear cover 32 through a pair of coupling holes 23a of the plurality of coupling holes 23a and 23b in the bracket coupling part 22. The cover screw 38 is coupled to the cover boss 36b through a single coupling hole 23b of the plurality of coupling holes 23a and 23b in the bracket coupling part 22. If the pair of second through holes 48a in the second coupling part 47 lines up with the pair of coupling holes 23a in a state in which the second coupling part 47 of the second supporter 42 is placed on the bracket coupling part 22, the screw (not shown) is coupled to the coupling part 36a of the rear cover 32 through the pair of second through holes 48a of the second coupling part 47 and the pair of coupling holes 23a of the bracket coupling part 22.

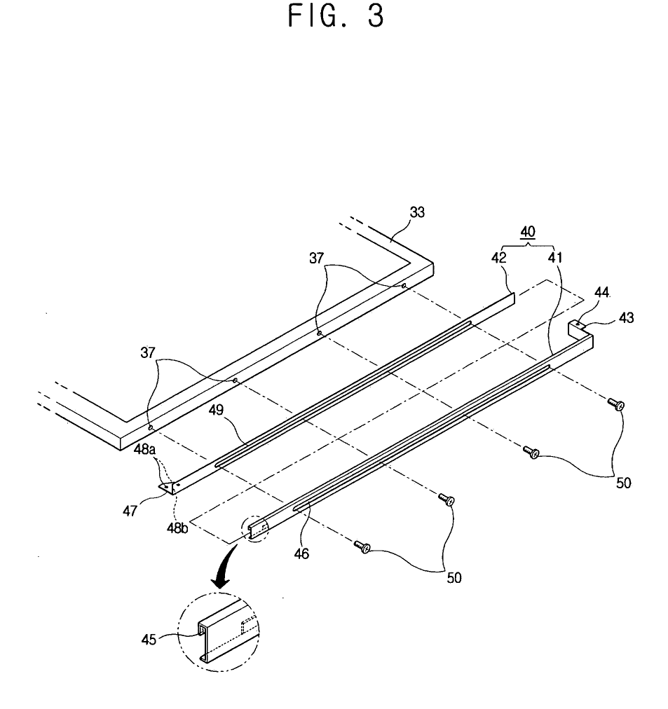

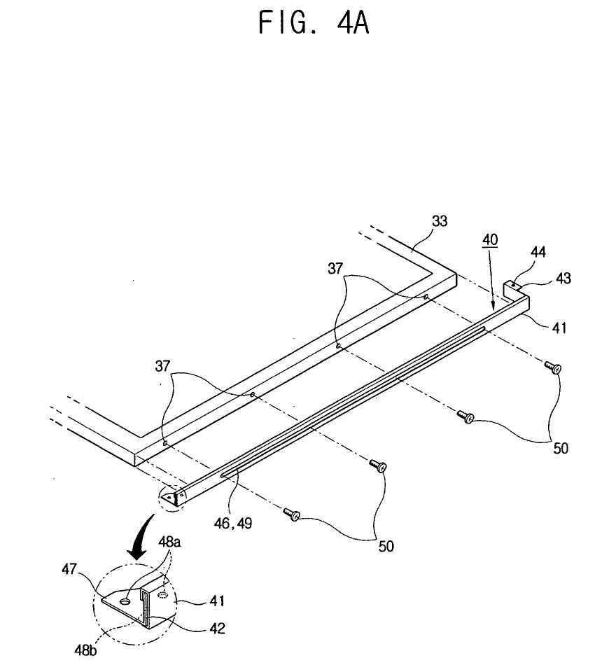

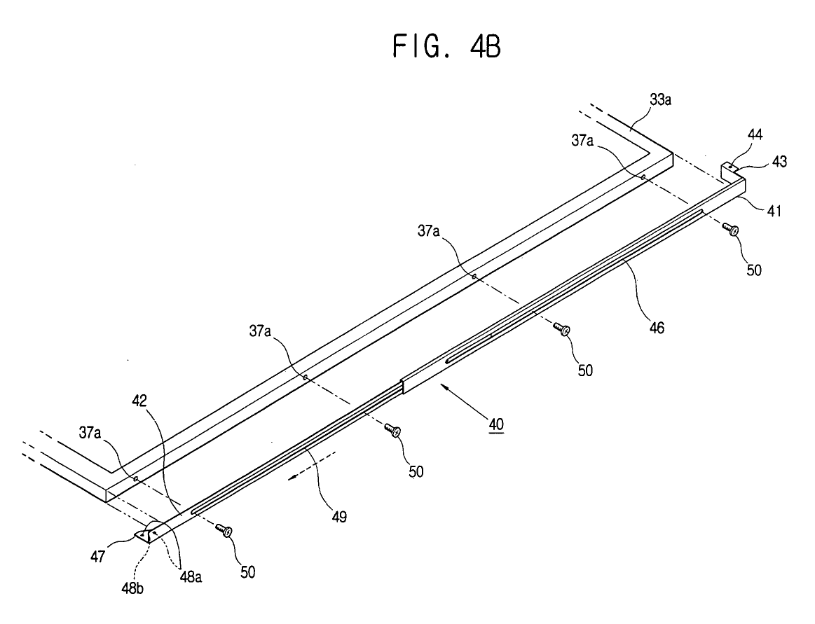

Hereinafter, a method of coupling the support brackets 40 to the opposite lateral sides of a small-sized display panel 33 will be described with reference to FIGS. 3 and 4A. Since the coupling of the support brackets 40 to the opposite lateral sides of the display panel 33 is performed in the same manner for both sides, only the coupling of one of the support brackets 40 to a right lateral side of the display panel 33 will be described with reference to FIGS. 3 and 4A. Here, the small-sized display panel 33 may comprise a 12.1 inch display panel, but is not necessarily limited thereto.

As illustrated in FIG. 3, the second supporter 42 is inserted into the guiding part 45 of the first supporter 41, and the second supporter 42 is slid along the guiding part 45 corresponding to a length of the side of the display panel 33. As illustrated in FIG. 4A, the second supporter 42 is accommodated in the guiding part 45 of the first supporter 41. At this time, the first opening part 46 of the first supporter 41 lines up with the second opening part 49 of the second supporter 42. The guiding part 45 forms a track along which the first and second supporters 41 and 42 are slidable with respect to each other such that the first and second supporters 41 and 42 cannot separate from one another when coupled together via the guiding part 45.

Then, the support brackets 40 of which the length is adjustable by the first supporter 41 and the second supporter 42 are positioned close to the opposite lateral sides of the display panel 33. Respective corners of the display panel 33 are accommodated in respective corners of the support brackets 40. The first coupling part 43 is placed on the upper part of the display panel 33, and the second coupling part 47 is moved to contact the lower part of the display panel 33.

The panel coupling holes 37 of the display panel 33 are exposed through the first and second opening parts 46 and 49 of the first and second supporters 41 and 42, respectively, thereby allowing coupling of the screws 50 to the panel coupling holes 37 through the first and second opening parts 46 and 49 which line up to communicate with each other. Accordingly, the support brackets 40 comprising the first and second supporters 41 and 42 are coupled to the lateral sides of the display panel 33.

Hereinafter, a method of coupling the support brackets 40 to opposite lateral sides of a display panel 33a having a larger size than the display panel 33 of FIG. 4A will be described with reference to FIG. 4B. Here, the large-sized display panel 33a may comprise a 17 inch display panel, but is not necessarily limited thereto.

First, the second supporter 42 accommodated in the guiding part 45 (not shown in FIG. 4B) of the first supporter 41 is slid along a dotted arrow direction in FIG. 4B, to expand an overall length of the support brackets 40 corresponding to a length of the lateral sides of the display panel 33a. The first and second supporters 41 and 42 may be first and second supporter plates 41 and 42, respectively.

The support brackets 40 having the expanded length are positioned close to the lateral sides of the display panel 33a. The respective corners of the display panel 33a are accommodated in the respective corners of the support brackets 40. The first coupling part 43 is placed in contact with the upper part of the display panel 33a, and the second coupling part 47 is placed in contact with the lower part of the display panel 33a.

A pair of panel coupling holes 37a positioned on an upper part of the display panel 33a are exposed through the first opening part 46, and another pair of panel coupling holes 37a positioned on a lower part of the display panel 33a are exposed through the second opening part 49, thereby allowing the coupling of the screw 50 to the panel coupling holes 37a through the first and second opening parts 46 and 49. Thus, the support brackets 40 comprising the first and second supporters 41 and 42 are coupled to the lateral sides of the display panel 33a.

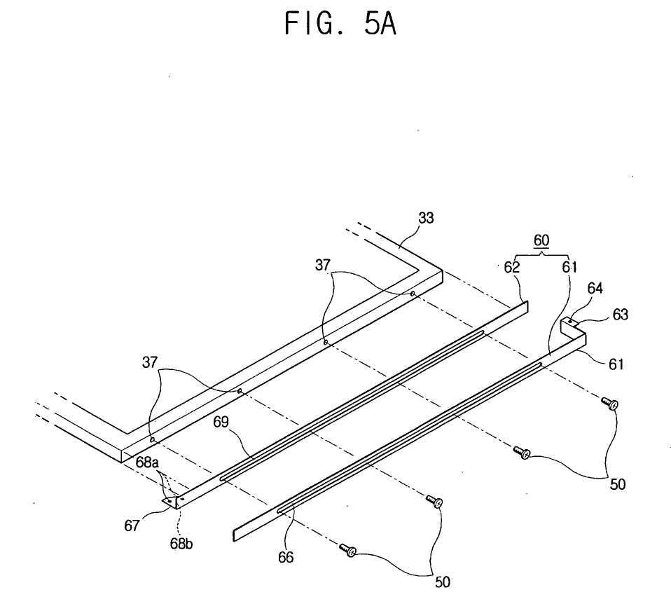

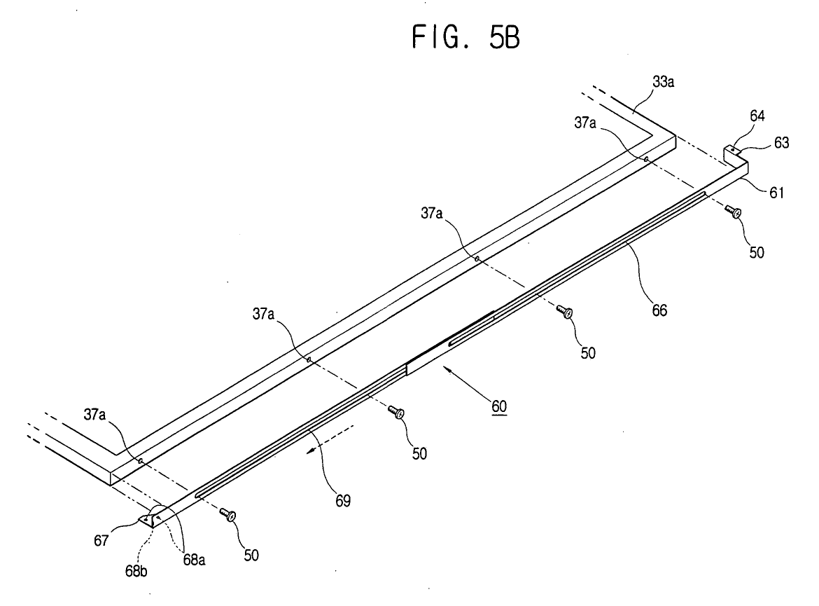

In the present embodiment of the general inventive concept, the second supporter 42 is accommodated in the guiding part 45 of the first supporter 41 to be slid along the guiding part 45. Alternatively, as illustrated in FIGS. 5A and 5B, an overall length of support brackets 60 may simply be changed by first and second supporters 61 and 62, without providing a guiding part (i.e., similar to the guiding part 45 in the first supporter 41 of the previous embodiment).

The first supporter 61 comprises a first coupling part 63 formed with a first through hole 64 on a first side thereof. The second supporter 62 comprises a second coupling part 67 formed with a plurality of second through holes 68a and 68b on a first side thereof.

As illustrated in FIG. 5A, after the second supporter 62 is positioned adjacent to a side of the display panel 33, the first supporter 61 is placed on the second supporter 62 to couple the support brackets 60 to the sides of the small-sized display panel 33. That is, the first supporter 61 and the second supporter 62 overlap with each other.

As the panel coupling holes 37 are exposed through a first opening part 66 and a second opening part 69 of the first and second supporters 61 and 62, respectively, which communicate with each other, screws 50 are inserted through the first and second opening parts 66 and 69 to be coupled to the panel coupling holes 37. Thus, the support brackets 60 comprising the first and second supporters 61 and 62 are coupled to the lateral sides of the display panel 33.

Hereinafter, a method of coupling the support brackets 60 to the opposite lateral sides of the display panel 33a having the size that is larger than the display panel 33 of FIG. 5A will be described with reference to FIG. 5B.

After an end part of the first supporter 61 overlaps with an end part of the second supporter 62 corresponding to a length of the side of the display panel 33a, the first supporter 61 and the second supporter 62 are attached close to the display panel 33a. As respective corners of the display panel 33a are accommodated in respective corners of the support brackets 60, the first coupling part 63 is placed in contact with the upper part of the display panel 33a, and the second coupling part 67 is placed in contact with the lower part of the display panel 33a.

At this time, a pair of the panel coupling holes 37a provided on the upper part of display panel 33a are exposed through the first opening part 66, and another pair of the panel coupling holes 37a provided on the lower part of the display panel 33a are exposed through the second opening part 69, thereby allowing the coupling of the screws 50 to the panel coupling holes 37a through the first and second opening parts 66 and 69. Thus, the support brackets 60 comprising the first supporter 61 and the second supporter 62 are coupled to the lateral sides of the display panel 33a.

A portable computer according to embodiments of the present general inventive concept comprises a support bracket which varies in length corresponding to a size of a display panel, therefore the support bracket may be used with display panels of various sizes.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A portable computer, comprising:
a computer main body;
a display part connected to the computer main body and having a display panel to display an image thereon;
a plurality of coupling parts formed on opposite side walls of the display panel;
a support bracket which supports the opposite side walls of the display panel and varies in length, and having a pair of supporters slidably coupled to each other; and
a coupling member which is coupled to one of the plurality of coupling parts to couple the support bracket to the display panel.

2. The portable computer according to claim 1, wherein a first one of the supporters is provided with a guiding part in a lengthwise direction, and a second one of the supporters is slidably accommodated in the guiding part.

3. The portable computer according to claim 2, wherein the supporters comprise opening parts which penetrate a plate surface thereof along the lengthwise direction, and the opening parts communicate with each other.

4. The portable computer according to claim 3, wherein the coupling member comprises a screw which is coupled to the respective coupling part through both the opening parts.

5. The portable computer according to claim 4, wherein the display part comprises a front cover which supports the display panel at a front thereof, and a rear cover which supports the display panel therebehind.

6. The portable computer according to claim 5, wherein the supporters comprise a flange which is coupled to the rear cover.

7. The portable computer according to claim 6, further comprising:
a hinge assembly which rotatably couples the display part to the computer main body, and the flange provided in the supporters is adjacent to the computer main body and is coupled to the rear cover together with the hinge assembly.

8. The portable computer according to claim 1, wherein the supporters comprise opening parts which penetrate a plate surface thereof along a lengthwise direction, and the opening parts communicate with each other.

9. The portable computer according to claim 8, wherein the coupling member comprises a screw which is coupled to the respective coupling part through both the opening parts.

10. The portable computer according to claim 9, wherein the display part comprises a front cover which supports the display panel at a front thereof, and a rear cover which supports the display panel therebehind.

11. The portable computer according to claim 10, wherein the supporters comprise a flange which is coupled to the rear cover.

12. The portable computer according to claim 11, further comprising:
a hinge assembly which rotatably couples the display part to the computer main body, and the flange provided in the supporters is adjacent to the computer main body and is coupled to the rear cover together with the hinge assembly.

13. A portable computer, comprising:
a computer main body;
a display part connected to the computer main body and having a display panel to display an image thereon;
a plurality of coupling parts which are formed on opposite side walls of the display panel;
a support bracket which supports the opposite side walls of the display panel and varies in length, and having a pair of supporters with respective portions that are overlapped with each other; and
a coupling member which is coupled to one of the coupling parts to couple the support bracket to the display panel.

14. The portable computer according to claim 13, wherein the supporters comprise opening parts which penetrate a plate surface along a lengthwise direction thereof through which the coupling member is inserted, and the opening parts communicate with each other.

15. A portable computer, comprising:
a main body part;
a display part hingeably connected to the main body part and having a display side, a rear side, and lateral sides extending between the display side and the rear side, the lateral sides having coupling holes; and
an adjustable support bracket coupled to at least one of the lateral sides of the display part via the coupling holes, the support bracket including a first supporter extending along a lower portion of the lateral side and a second supporter extending along an upper portion of the lateral side such that the first and second supporters overlap with each other at a middle portion of the lateral side.

16. The portable computer according to claim 15, wherein:
the first and second supporters have first and second openings, respectively, extending along corresponding lengths thereof; and
the portable computer further comprises screws to couple the first and second supporters to the lateral sides of the display part via the coupling holes.

17. The portable computer according to claim 16, wherein the screws are arranged along the length of the lateral side of the display part.

18. The portable computer according to claim 16, wherein at least one of the screws is coupled to a coupling hole in the middle portion of the lateral side through both the first and second openings.

19. The portable computer according to claim 15, wherein a size of the support bracket is adjustable by moving the first and second supporters with respect to each other.

20. The portable computer according to claim 15, wherein the first supporter comprises a guiding part to accommodate the second supporter such that the first and second supporters are slidably engaged, and the guiding part provides a track along which the second supporter is movable and is inseparable from the first supporter.

21. An adjustable support bracket to support a display part usable with a portable computer, the support bracket comprising:
a second supporter plate to be coupled to a lateral side of the display part along a second portion of a length thereof; and
a first supporter plate to be coupled to the lateral side of the display part along a first portion of the length thereof to overlap with the second supporter plate and having a guiding part to engage the second supporter plate to form a track along which the first and second supporter plates are slidable with respect to each other.

22. The adjustable support bracket according to claim 21, wherein the first and second supporter plates comprise first and second openings extending along respective lengths thereof through which screws couple the first and second supporter plates to the lateral side of the display part.

23. A support bracket usable to support display panels of various sizes, the support bracket comprising:
a bracket assembly having first and second plates to be coupled to one or more lateral sides of a display panel at first and second ends of the lateral sides, respectively, the first and second plates having an overlap area with respect to each other that is adjustable such that a size of the bracket assembly is adjustable to allow the first and second plates to collectively extend along lengths of the lateral sides.

24. A support bracket usable to support display panels of various sizes, the support bracket comprising:
a first supporter plate having a first coupling portion extending therethrough;
a second supporter plate having a second coupling portion extending therethrough; and
a guiding part to slidably couple the first and second supporter plates together,
wherein a plurality of couplers extend through the first and second coupling portions to couple the first and second supporter plates to a lateral side of a display part.
